(19) United States
(12) Patent Application Publication
(10) Pub. No.: US 2017/0358616 A1
(43) Pub. Date: Dec. 14, 2017

(54) ACTIVE PIXEL IMAGE SENSOR BASED ON CMOS TECHNOLOGY WITH ELECTRON MULTIPLICATION

(71) Applicant: Teledyne e2v Semiconductors SAS, SAINT EGREVE (FR)

(72) Inventors: Pierre FEREYRE, Voreppe (FR); Frédéric MAYER, Voiron (FR)

(21) Appl. No.: 15/540,054

(22) PCT Filed: Dec. 15, 2015
(86) PCT No.: PCT/EP2015/079833

§ 371 Date: Jun. 27, 2017

(30) Foreign Application Priority Data
Dec. 29, 2014 (FR) 1463367

(51) Int. Cl. H01L 27/146; H01L 31/0224; H04N 5/351; H04N 5/3745

(52) U.S. Cl. CPC H01L 27/14612; H04N 5/3745; H01L 31/022408; H01L 27/14603; H04N 5/351

(57) ABSTRACT

In an active pixel image sensor using CMOS technology formed within a substrate of a first type of conductivity P, each pixel comprises a photosensitive element PHD producing charges under the effect of light and a structure for multiplication of charges EM. The multiplication structure comprises at least one isolated multiplication gate G1, G2 adjacent to a pinned diode DI at a fixed internal potential V_{bi}, and the isolated gate is adapted for receiving a series of alternations of potentials, alternately creating under the isolated gate a charge collection well and a barrier, relative to the internal potential level of the diode DI. The isolated gate and the semiconductor region under the isolated gate are configured in such a manner that the charge collection well created under the gate comprises two parts: a first part a, adjacent to the pinned diode, at a potential level further from the photodiode internal potential level than that of a second part b, this second part being adjacent or not to the pinned diode.

### FIELD

The invention relates to active pixel image sensors, using CMOS technology, with electron multiplication.

The basic structure of an active pixel of image sensors using CMOS technology comprises a photosensitive element, which collects the electrons photo-generated by light in an integration phase, an element for storing the photo-generated charges, which allows the pixel to be read, and a few transistors which notably provide reset, transfer, and charge/voltage conversion functions.

The photosensitive element is usually a photodiode, and preferably a self-biased, or “pinned”, photodiode. In such a photodiode, if the example of a structure formed within a P-doped semiconductor substrate is taken, the N diffusion layer on the surface of the substrate is covered with a thin, highly P⁺ doped, diffusion layer, which allows the surface potential to be fixed at that of the substrate. Such a photodiode then has an equal constant internal potential referred to as ‘built-in potential’ and which depends on the concentrations of the dopants.

The sensors referred to as electron multiplication sensors additionally incorporate, within the active pixel structure itself, an electron multiplication device. The effect of multiplication of electrons is obtained by causing movements of electrons, within the semiconductor, with acceleration voltages such that secondary electrons are ejected from the semiconductor, by effect of impact ionization. For the same number of photons, the pixel therefore produces more electrons, which are transferred to the storage region.

The invention concentrates more particularly on sensors whose multiplication structure comprises at least one isolated gate adjacent to a semiconductor element constructed as a pinned photodiode, in other words whose internal potential rises to a fixed value referred to as ‘built-in potential’, as previously described.

This semiconductor element may be the photosensitive element of the pixel, as for example described in the application FR2961347. The multiplication then takes place at the same time as the photo-generation of electrons, inside the photodiode, the time for which the integration phase of the pixel lasts. All of the photo-generated and multiplied electrons are subsequently transferred to the storage node, for the read phase of the pixel.

The semiconductor element may also be an element specific to the multiplication structure, as described for example in the applications EP2503596, EP2503776. The multiplication structure then comprises two multiplication gates on either side of a pinned diode, which serves as a transit region for the charges that come and go during the multiplication phase, between the region under one gate and the region under the other gate, with the frequency of the alternations in potential applied to them. More precisely, the movement of the electrons, from the region under one gate towards the region under the other gate, is controlled by applying a “low” potential to the first gate, creating under this gate a potential barrier, at a low potential level with respect to the fixed potential of the diode, and by applying a “high” potential to the second gate, creating under this gate a well allowing the electrons to be collected, at a sufficiently high potential level with respect to the fixed internal potential of the diode, in order to allow the phenomenon of impact ionization. At the following alternation, the “high” and “low” potentials applied to the gates are reversed. The number of alternations depends on the desired multiplication factor. At the end of the multiplication phase, all the electrons are stored in the potential well under one of the gates and transferred to the storage node of the pixel.

### Technical Problem

These multiplication structures allow the response of the sensor to be improved, especially for low levels of light. The signal level is increased, with a gain for example of the order of 5 to 10, which is in proportion to the number of alternations of high and low potentials applied to the multiplication structure. Since the noise level (known as noise floor) is constant, the signal-to-noise ratio for low levels of light is improved. However, on the other hand, saturation is reached sooner.

This is illustrated schematically in FIG. 1. The solid curve 1 shows the number of electrons read at the output as a function of the number of photons received in a standard active pixel, in which the number of electrons produced is equal to the number of photo-generated electrons (if the noise is ignored). The discontinuous curve 2 shows the number of electrons read at the output as a function of the number of photons received in an active pixel with a multiplication structure: the number of electrons produced is equal to the number of electrons photo-generated and multiplied. It can be seen that the multiplication allows the signal detection level of the sensor to be lowered: the noise floor level (the noise of the read chain) will be exceeded sooner. However, saturation will also be reached sooner, at B′, except where the electron multiplication gain is modulated as a function of the level of light, as provided in the aforementioned Patent applications EP2503596 and EP2503776: their idea is to carry out, for each read phase of a pixel, several (two) cycles of integration and reading of charges, with a multiplication gain which is different each time. The variation in gain is obtained by varying the number of alternations applied and/or the duration of the integration phase. It is the read circuit which subsequently determines, by test, which is the signal to be conserved for each pixel. In this way, sensors can be fabricated with a wide dynamic range, capable of operating both in environments with very low light or very strong light and also sensors capable of supplying images which are themselves very contrasted.

However, this is obtained at the expense of a greater complexity of the electronics in order to provide the sequencing and the repetition of the various phases for acquisition/transfer/multiplication within the pixel, while at the same time accommodating the constraints of reading by correlated double sampling (CDS reading).

### SUMMARY

The aim of the present invention is to provide another solution to this problem. The idea is to obtain, by design, an intrinsic modulation of the gain in the multiplication structure of the pixel. This intrinsic modulation, which is exerted within each pixel, allows the dynamic range of the sensor to be increased, both towards the low levels (detection earlier) and towards the high levels (saturation later).

It has been seen that the principle of multiplication within the pixel uses the phenomenon of impact ionization. In the structure based on an isolated multiplication gate adjacent to a pinned diode at a fixed potential, this phenomenon occurs when a charge collection well is created under the gate by application of a high potential, higher than the fixed potential of the diode, whenever the electric field established between this well and this diode region, owing to their difference in potential, is sufficiently high.

As the well is filled up, the volume of charges in the well tends to lower the internal potential of the well: the electric field decreases. Beyond a critical value, the electric field is no longer sufficient to allow impact ionization.

The idea on which the invention is based is to exploit this natural effect of damping of the electric field with the quantity of charges, by an astute configuration of the “volume” of the well, in order to progressively reduce the multiplication gain within a pixel, and to switch it off at an opportune time.

Referring again to FIG. 1, what it is desired to obtain in the invention is a curve of time variation of the signal from the pixel corresponding to the dashed curve 3 in the figure: in other words, detecting very early, at the point A or before, but saturating very late, at the point B.

For this purpose, the invention provides an astute configuration of the multiplication gate, allowing, with this configuration, a potential well to be created under the gate which consists of two parts: a deeper part, adjacent to the pinned diode, and a shallower part, adjacent or not to this diode. The part A is configured (size in cm², depth in volts) in such a manner that the maximum volume of charges that the part A can contain determines the moment of extinction of the phenomenon of impact ionization.

At the start of the multiplication, the electrons coming from the pinned diode region are attracted by the deeper part of the well, since it is between this well and the semiconductor element that the highest electric field is exerted. This deeper part of the well will fill up with charges more quickly than a well would have done which had the same depth under the whole gate surface.

When this deeper part of the well is full, the electrons can continue to pour into the well, while overflowing into the shallower part. At this moment, the multiplication effect switches off. The electric field between the pinned diode region and the well goes below the critical value. The structuring of the well in two parts, with one part deeper than the other, adjacent to the pinned diode region, thus enables the threshold to be adjusted which allows, by construction, the effect of impact ionization to be extinguished.

More precisely the invention provides an image sensor with active pixels using CMOS technology formed within a substrate of a first type of conductivity. Each pixel comprises a photosensitive element producing charges under the effect of light and a structure for multiplication of charges. The multiplication structure comprises at least one isolated multiplication gate adjacent to a pinned diode at a fixed internal potential, the isolated gate being designed to receive a series of alternations of potentials, alternately creating, under the isolated gate, a well for collecting the charges and a barrier, relative to the internal potential level of the pinned diode. According to the invention, the isolated gate and the semiconductor region under the isolated gate are configured in such a manner that the well created under the gate comprises two parts: a first part, adjacent to the pinned diode, at a potential level further from the photodiode internal potential level than that of a second part, this second part being preferably adjacent to the pinned diode.

In one implementation, the semiconductor region under the isolated gate comprises two parts, a first part which is doped with the second type conductivity in order to establish the first part of the well, and a second part which is doped with the first type of conductivity in order to establish the second part of the well.

In another implementation, the two well parts are established by performing a differentiated doping of the gate itself: the gate made of polycrystalline silicon is doped with the second type of conductivity in a first gate part in order to establish the first part of the well; it is doped with the first type of conductivity in a second part in order to establish the second part of the well. The difference in doping between the two gate parts leads to the development of a different metal/semiconductor extraction potential within each part, depending on the type of doping; using the same gate voltage, the two parts of the well according to the invention are thus established.

In another implementation, the isolated gate is divided into two sub-gates: a first sub-gate in order to establish the first part of the well, and a second sub-gate in order to establish the second part of the well. During the alternations intended to create a charge collection well under the gate, the two sub-gates are adapted for simultaneously receiving different high potentials, so as to fix the semiconductor region under the first sub-gate at a potential level which is further from the internal potential level of diode than the potential level of the semiconductor region under the second sub-gate.

The invention is applicable to an active pixel structure with multiplication stage which can be formed within the pixel, and in the photosensitive element of the pixel, or else within the pixel, and outside of the photosensitive element.

### BRIEF DESCRIPTION OF THE DRAWINGS

Other features and advantages of the invention will become apparent upon reading the detailed description that follows and which is presented with reference to the appended drawings in which:

FIG. 1 illustrates schematically the response curve of an active pixel, in number of electrons as a function of the number of photons received, with and without multiplication stage;

FIG. 2 illustrates schematically the general principle of a well in two parts under a multiplication gate according to the invention;

FIGS. 3 and 4 are cross-sectional and top views of a known active pixel structure with multiplication stage, in an example where the multiplication stage comprises two multiplication gates on either side of an intermediate region at a fixed potential;

FIGS. 5 and 6 are schematic cross-sectional and top views of such a multiplication structure with two gates, according to a first embodiment of the principle of the invention;

FIG. 7 shows the control signals applied to these two gates in the multiplication phase;

FIG. 8 illustrates the barrier and the well created respectively under one gate and under the other, during one of the alternations, with such a multiplication structure according to the invention;

FIGS. 9 and 10 are schematic cross-sectional and top views of a multiplication structure, according to a variant of the first embodiment;

FIGS. 11 and 12 are schematic cross-sectional and top views, according to a second embodiment of the principle of the invention;

FIG. 13 shows the control signals applied to the gates of the preceding structure in the multiplication phase; and

FIG. 14 shows various exemplary forms (surfaces) of the two well parts under a multiplication gate according to the invention for a multiplication structure whose pinned diode is the photodiode of the pixel.

### DETAILED DESCRIPTION

The invention is described by taking the example of an image sensor fabricated using a CMOS technology on a semiconductor substrate with P-type doping. The photodiodes of the pixels are formed in it by highly doped regions of the N type. Here, the useful photo-generated charges that are multiplied in the pixels are electrons, but the invention is applicable to similar devices in which the useful charges are holes. For this case, the types of conductivity of the various doped regions indicated hereinafter will be reversed and the potentials applied to the various gates for the charge transfers will be of opposite signs to those indicated hereinafter.

A basic structure of a multiplication stage EM of a pixel comprises an isolated multiplication gate Gm adjacent to a diode DI self-biased at an internal potential Vbi referred to as built-in potential. In FIG. 2, the semiconductor regions corresponding to these elements Gm and DI are very schematically illustrated as a top view. Typically, the gate Gm is a gate formed from polysilicon and isolated from the substrate by a layer of dielectric of appropriate thickness (in order to withstand the potential difference applied between the gate and the substrate). The diode DI is formed from a N-doped region, on which is formed a thin P-doped region at the surface held at a reference potential, which is the reference potential of the substrate (ground). It has been previously seen, with reference to the aforementioned patent application FR, that this diode could be the photodiode of the pixel itself. In the opposite case, the diode is specific to the multiplication structure in which it serves as a transit region, and this structure is generally protected from the light by an optical mask.

According to the invention, the gate Gm and the region under the gate are configured in two parts a and b such that, when (during a multiplication phase) a high potential Vh is applied to this gate, a potential well relative to the fixed internal potential Vbi of the adjacent diode region, DI, is created. Furthermore, this well is in two parts: a part a deeper than a part b and the part a is adjacent to the diode region DI.

Thus, the well is deeper in the part a. Since this part a is adjacent to the diode region, an electric field is exerted which attracts electrons, accelerating them from the diode region DI towards the well part a. This field is sufficiently high to enable impact ionization, liberating electrons from the semiconductor, the electrons thus removed then increasing the quantity of free electrons. Saying that the electric field is sufficiently high means that this field is higher than a critical value which is of the order of 100 KV/cm.

The part a of the well bounds a corresponding volume of charges: this volume is bounded by the surface (in cm²) of the part a and the potential difference ΔV₁ between the parts a and b, in other words the depth (in volts) of the part a relative to the part b.

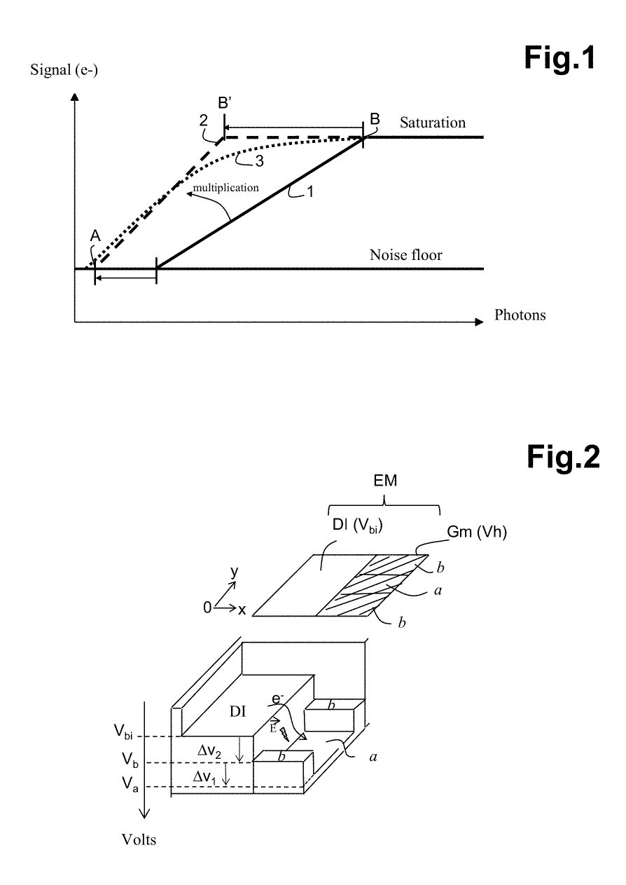

More precisely: the diode region DI is at the potential V_{bi}; the part a is, in the absence of charges, at an internal potential Vₐ; the part b, on the other hand, is at an internal potential V_{b}. The potentials verify V_{bi}<V_{b}<Vₐ; and Vₐ, V_{b} only depend on the voltage applied to the gate and the characteristics of this gate and of the semiconductor region under the gate; and Vₐ and V_{b} are such that, when the “pseudo” volume defined by the surface area (in cm²) of the part a and its depth (in volts) relative to the part b is entirely filled with charges, the potential difference between the region DI and the well is reduced to ΔV₂=V_{bi}−V_{b}. This difference no longer allows the electrons to be sufficiently accelerated to enable impact ionization; the multiplication shuts off. This corresponds to the point B on the curve 3 in FIG. 1.

Before getting to this point, the “real” potential difference between the diode region DI and the part a of the well decreases at the rate of the alternation of potentials applied to the gate. It may be said that the level of charges by volume in the well part a climbs progressively, with a damping effect, by filling this part a then overflowing into the part b; and, at a moment in time corresponding to the point B of saturation of the curve 3 in FIG. 1, there is an intrinsic extinction of the phenomenon of impact ionization: the to and fro motion induced on the electrons by the following alternations no longer allows them to be multiplied.

Using the invention, the gain of the multiplication structure can thus be damped until it is extinguished, in an intrinsic manner, by configuring the “volume” of charges that the part a of the well under the gate can contain. “Configuring” means choosing appropriate surfaces and depths of the parts a and b of the well created under the gate.

The astute configuration of an isolated multiplication gate according to the invention thus allows the signal level to be enhanced in a low light environment and hence some signal to be detected very early on, at the point A (FIG. 1), and in a high light environment, it allows the multiplication to be damped and extinguished so as not to saturate the signal level before the point B.

This configuration of isolated multiplication gate according to the invention is applicable to active pixel structures with multiplication stage, both those in which the multiplication stage is formed within the pixel and in the photosensitive element of the pixel, as well as those in which the multiplication stage is formed within the pixel but outside of the photosensitive element. It is this that will now be described, taking first of all the case of an active pixel with multiplication stage formed outside of the photosensitive element, according to the teaching of the aforementioned applications EP2503596 and EP2503776.

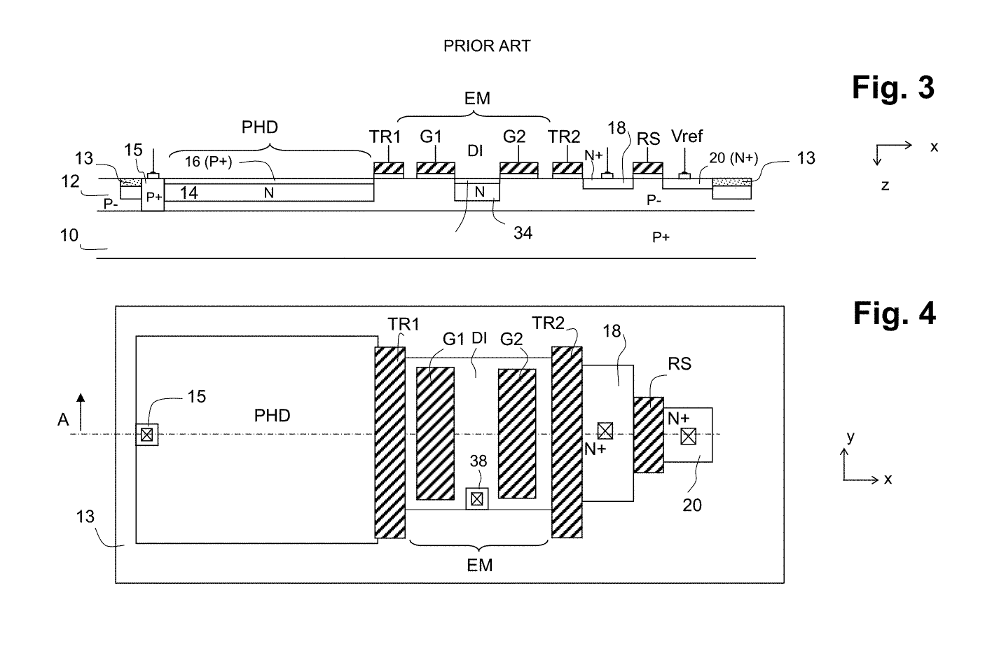

FIGS. 3 and 4 show the main elements of such an active pixel, as a top view and in cross section. The pixel is formed within a substrate 10 which preferably comprises an active semiconductor layer 12 of the P type, lightly doped (the symbol P⁻ is used to denote this low level of doping), formed on the surface of a more highly doped layer (P+). The pixel is isolated from the neighbouring pixels by an insulating barrier 13 which completely surrounds it. This barrier may be a surface isolation trench on top of a well of the P type.

The pixel comprises a region of pinned photodiode PHD whose perimeter follows the contour of a semiconductor region of the N type implanted into a part of the depth of the active layer 12. This implanted region is covered by a surface region 16 of the P+type, which is held at a reference potential. In the simplest case, this reference potential is the ground potential of the substrate of the P+ type situated under the active layer; the surface region 16 is held at this ground potential by means of a deep diffusion 15 of the P+ type which touches this region 16: either this diffusion 15 meets the substrate 10, or an electrical ground contact is provided on this diffusion 15.

A node for storage of charges is provided outside of the photodiode region PHD; this is a diffusion 18 of the N type within the active layer 12, separated from the photodiode region by a succession of two transfer gates TR1 and TR2 and a multiplication stage EM between these two transfer gates. It is this storage node which subsequently allows the pixel to be read, by charge/voltage conversion: a contact is formed on the diffusion 18, in order to connect it to the gate of a follower transistor not shown, which transforms the quantity of charges contained in the storage node into an electrical voltage level.

Another gate RS, called reset gate, allows the charges to be emptied from the storage node to an evacuation drain 20 which is a region of the N+ type connected to a positive reset potential Vref.

The first transfer gate TR1 allows the transfer of electrons from the photodiode to the multiplication stage to be enabled at the end of an integration time.

The second transfer gate TR2 allows the transfer of electrons from the multiplication stage to the storage node 18 to be enabled at the end of a multiplication phase.

The multiplication stage EM comprises two multiplication gates G1 and G2 separated by a pinned diode DI; it is constructed like the photodiode (but not necessarily with the same doping levels): there is thus a diffused region 34 of the N type within the active layer 12, which is covered by a surface region 36 of the P+ type. This region is held, for example by a deep diffusion (not shown) analogous to the region 15, at the reference potential of the active layer 12, which is here the ground potential of the substrate 10.

In practice, the transfer gates, the multiplication stage and the storage node are protected from the light by a protection layer acting as an optical mask (not shown); only the photodiode receives the light. In the various figures, the elements composing the pixel are not shown to scale: in reality, the major part of the surface of the pixel is reserved for the photodiode.

It should also be noted that the diode of the multiplication stage is a transit region for the electrons; it is not a storage region (in contrast to the regions under the multiplication gates) and can therefore be narrow.

The operation of this pixel structure with multiplication stage will now be briefly explained.

At the end of an integration period, the electrons photo-generated in the photodiode are transferred under the multiplication gate G1 by application of suitable control signals to the transfer gate TR1 and to the multiplication gate G1.

The multiplication phase can begin. During this phase, the transfer gates are held at potentials that are sufficiently low to create impenetrable barriers for the charges contained in the semiconductor region corresponding to the multiplication stage.

During the multiplication phase, an alternation of high and low potentials is applied in phase opposition to the gates G1 and G2, whereas the diode region DI is at the constant potential V_{bi}. At each alternation, one region under a gate thus forms a charge collection well (electrons), with a higher potential than the potential V_{bi} of diode DI, whereas the region under the other gate forms a barrier to the passage of the charges (electrons), with a potential lower than the potential V_{bi}. The roles (hence the potentials) are then reversed at each alternation.

The electrons are thus alternately accelerated from the gate G1 towards the gate G2 and vice versa. The voltages applied to the gates G1 and G2 are sufficient to allow impact ionization: the accelerated electrons knock off other electrons, multiplying the number of electrons by a coefficient a little higher than 1 which depends on the applied voltages.

During each multiplication operation, the diode region DI is traversed by the packets of electrons which transit alternately from one multiplication gate to the other. The number of alternations may be several hundreds or thousands. The overall amplification coefficient depends on the applied voltages and on the number of alternations, and may go from 5 to 10 for example for a cycle of 1000 alternations.

At the end of the multiplication phase, the electrons are stored under the gate G2; from there, they are transferred to the storage node 18 through the transfer gate TR2. The read phase for the pixel can begin.

By applying the principle of the invention presented with reference to FIG. 2, the configuration of the gates G1 and G2 will be modified, including the semiconductor region under these gates, in such a manner that the charge collection well created under a gate comprises a first part a deeper than a second part b. This configuration may be obtained in different ways.

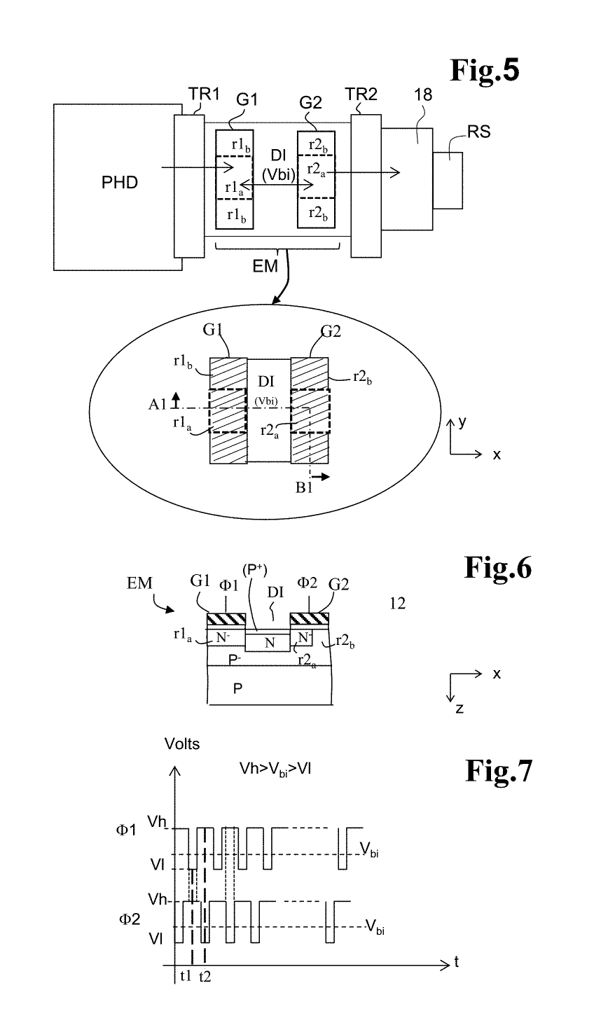

A first example of creation of a well with two levels according to the invention is illustrated in FIGS. 5 to 8. The deeper well part a is obtained by implanting, under each multiplication gate, an N-doped region. The size of the implanted surface under the gate (size of the mask) and the concentration of dopants determines “the volume” of the part a of the well when a high potential Vh is applied to a multiplication gate.

The characteristics of each multiplication gate with a partial N implantation under the gate combined with the parameters characteristic of the diode DI (concentrations of dopants), allow the potential differences Δvᵢ and Δv₂ in FIG. 3 and the “extinction” threshold of the impact ionization phenomenon to be set.

FIG. 5 shows a corresponding multiplication stage EM as a top view, and FIG. 6 a cross-sectional view along the broken line A1-B1. Taking the gate G2: the surface bounded by the dashed line on this gate corresponds to the N-implanted region r2ₐ under this gate. It forms a strip under the whole gate length (along the axis x in the figures) so as to be adjacent on one edge to the diode region DI, allowing the controlled multiplication effect according to the invention, and adjacent on the opposite edge to the semiconductor region under the transfer gate TR2; it is this that subsequently allows the transfer of all the charges, which are sitting under this multiplication gate, to the storage node 18 of the pixel (a potential adapted to enable this transfer being applied to the transfer gate).

The remaining region r2_{b} under the gate is not implanted: referring again to FIG. 3, this is a E-doped region (active layer 12). These parts r2ₐ and r2_{b} allow the parts a and b of the charge collection well to be respectively formed under the gate G2 when a high potential Vh is applied to this gate, according to the principle of the invention (FIG. 2).

The gate G1 may be configured in the same way, as illustrated: the part r1ₐ thus corresponds to an N-implanted semiconductor region under the gate G1 in the form of a strip over the whole gate length, and the remaining part r1_{b} is not implanted (E region of the active layer 12). This example allows a symmetrical configuration of the two multiplication gates, in the form of strips. In the example, the part r1ₐ forms a central strip, framed on either side by two lateral strips (along the direction y) forming the part r1_{b}. It is possible for the part r1_{b} to only comprise a single strip.

As a variant, the gate G1 (but not the gate G2) may have a configuration in the form of a U such that the part r1ₐ is adjacent on one edge to the diode region DI (for the multiplication effect), and that on the other edges, the part r1ₐ is surrounded by the part r1_{b}. In other words, this part r1_{b} forms a “U” around the part r1ₐ when seen from above.

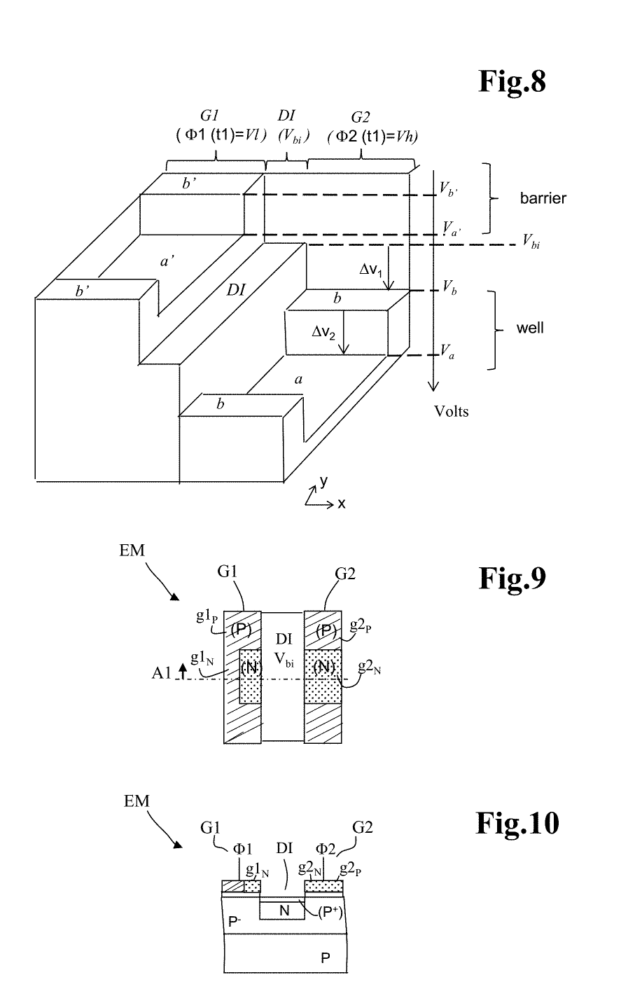

FIG. 7 shows the alternations of voltage on the control signals, Φ1 (for the gate G1) and Φ2 (for the gate G2), and FIG. 8 shows the potential levels induced in this manner within the semiconductor volume of the multiplication stage EM, during an alternation during which the gate G1 receives a low potential V_{I} and the gate G2 a high potential Vh (FIGS. 7, Φ1 and Φ2 at the time t1).

This FIG. 8 shows that, when the low potential VI is applied to the gate G1, a potential barrier is formed under the gate G1 which is also in two parts a′ and b′: the first part a′ is at a level V_{a′} deeper (higher in potential) than the level of the part b′, and therefore V_{b′}<V_{a′}<V_{bi}. The configuration of the volume under the gate in two parts is inherent to the configuration of a gate with an implantation of N and P differentiated dopants under the gate, which induces a different metal/semiconductor extraction potential in the two parts.

It has been seen that, in the multiplication phase, a series of high potential Vh and low potential VI alternations is applied to the gates G1 and G2, in order to create the to and fro motion of the electrons, from one region under a gate to the other, via the diode region. The form of the signals Φ1 and Φ2 respectively applied to the gates G1 and G2 is illustrated in FIG. 7. The signals Φ1 and Φ2 are signals in phase opposition. However, care is taken to avoid the two gates being able to be simultaneously at the low level VI, so as not to lose charges. This is avoided by providing a duration of application of the potential at the high level Vh to a gate which is longer and “encompasses” the duration of application of the potential at the low level VI to the other gate.

From a practical standpoint, these configurations of the gates G1 and G2 are achieved by ion implantation of the corresponding impurities into the active layer 12, using a mask bounding the parts r1ₐ and r2ₐ. The depositions of the gate insulator and of the gate polysilicon are subsequently carried out.

For the ion implantation of the regions r1ₐ and r2ₐ, a dose of dopants of the N type of 10¹⁶ atoms/cm³ will be able to be used, for a layer 12 (FIGS. 3 and 10) of active silicon of the P⁻ type doped at 5.10¹⁶ atoms/cm³.

The top and cross-sectional views in FIGS. 9 and 10 show another example of the creation of a potential well at two levels according to the invention. In this example, it is not the region of semiconductor under the gate which is implanted in a differentiated manner in order to create the potential well in two parts a and b, but the polysilicon gate. Thus, as illustrated in these figures, a part g1_{N} of gate G1 is implanted with the N type, and the remaining part g1ₚ is implanted with the P type. The same is true for the parts g2_{N}, g2ₚ of the gate G2. In the example, it has been chosen to show the case where the two gates G1 are not configured in an identical manner: seen from above, the region under the gate G2 has a configuration in strips, and the region under the gate G1 has a configuration in a “U” shape.

This mode of creating the potential well at two levels is advantageous in that the process of implantation of the gates is then completely self-aligned onto the gate; there is no diffusion of dopants into the diode region DI, and the characteristics of the multiplication structure are better controlled.

On the downside, the potential difference which is obtained in the semiconductor between the part under the N-implanted gate region and the P-implanted gate region, in other words the ΔV₁ in FIG. 3, will generally be lower, by the order of 1 volt, which has an impact on the gain damping curve: saturation is reached more quickly.

The two embodiments of the invention which have just been presented have in common that the potential difference ΔV₁ between the two parts a and b of the region under a gate is obtained using the same gate voltage. This potential difference ΔV₁ is established at a value which depends on the characteristics of this gate (technology, concentration of the various dopants, thickness and nature of the insulator). The term gate is to be understood in its wider sense, in other words including the gate (in other words the gate polysilicon) and the semiconductor region under the gate.

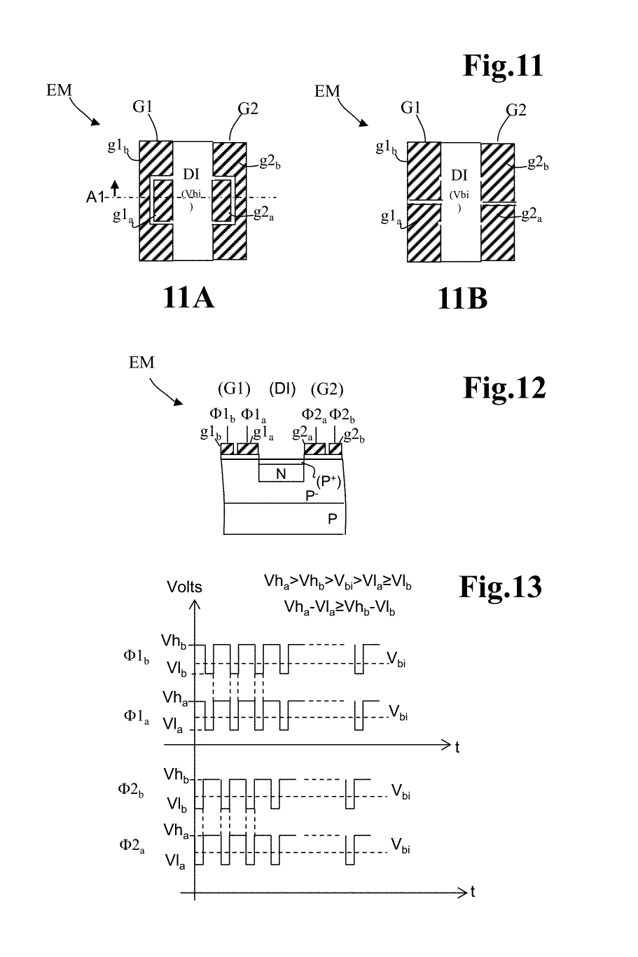

FIGS. 11 to 13, illustrate another exemplary embodiment of the invention. In this embodiment, a differential doping is not carried out, either of the gate itself or of the semiconductor under the gate. Instead, the gate itself is divided into two gate parts, in other words into two sub-gates: g1ₐ and g1_{b}, for G1, g2ₐ and g2_{b} for G2, and the two sub-gates of a gate are controlled with synchronous control signals, but offset in potential, so as to obtain, in the multiplication phase, a well under each gate which is in two parts a and b (or a′ and b′) (FIG. 8) separated from each other by a potential difference which is held fixed not by the technology (differential doping) but by the difference in voltage simultaneously applied to the two sub-gates.

FIG. 11 shows two examples of dividing up the gates G1 and G2. The example 11A corresponds to a configuration in a “U” shape: the first parts g1ₐ and g1_{b} are each adjacent on one edge to the diode, and each is surrounded on the other edges by the second part, respectively g1_{b} and g2_{b}, which has a U shape. The example 11B corresponds to a configuration as two juxtaposed strips, each adjacent on one edge to the diode DI and adjacent on the opposite edge to the transfer gate (TR1 for G1, TR2 for G2).

To each gate G1, G2, there correspond two synchronous control signals: Φ1ₐ and Φ1_{b}, respectively applied to the two sub-gates g1ₐ and g1_{b}; Φ2ₐ and Φ2_{b} respectively applied to the two sub-gates g2ₐ and g2_{b}.

Taking for example the signals Φ1ₐ and Φ1_{b} (FIG. 13), these are synchronous.

During the alternations of the multiplication phase, the signal Φ1ₐ alternately imposes a high potential Vhₐ, higher than the high potential Vh_{b} imposed by the signal Φ1_{b}, and a low potential VIₐ which may be identical to or different from the low potential VI_{b} imposed by the signal Φ1_{b}. In the latter case, the practical “realization” of the synchronous signals Φ1ₐ and Φ1_{b} is simpler, because they are just shifted in amplitude from one alternation to the other. For example, Φ1ₐ is a pulsed signal varying between 2 and 6 volts and Φ1_{b} is a pulsed signal varying between 0 and 4 volts. In the case where the same low level is applied to the two gate parts, the barrier under the gate will be at a uniform level under the whole gate surface, instead of also being in two parts a′ and b′, at two separate potential levels, as shown in FIG. 8.

What has just been said for the signals Φ1ₐ and Φ1_{b} also goes for the signals Φ2ₐ and Φ2_{b}.

In this embodiment, and in the case of a configuration of the gate G2 in the form of a “U”, the sub-gate g2ₐ is not adjacent to the transfer gate TR2. The transfer of the charges under the gate G2, to the storage node of the pixel, is obtained (in that transfer phase) by a simultaneous application to the two sub-gates g2ₐ and g2_{b} of identical or different potentials, chosen as a function of the potential which is established in the semiconductor region under the transfer gate during this transfer phase.

In practice, this implementation which includes the division of each multiplication gate into two sub-gates requires the doubling of the multiplication gate control lines: it is more particularly intended for sensors with wide pixels, which offer the space necessary for the feed lines for the additional signals on each pixel.

The invention is also applicable, as already indicated, to a multiplication stage which would be integrated into the photodiode of the pixel itself. In this case, the pinned diode of the multiplication stage is the photodiode itself, which then also constitutes a storage area for the multiplied electrons. The multiplication stage may comprise a single multiplication gate and this multiplication gate may be entirely included within the photodiode region, or have one edge adjacent to an isolated gate for transfer of the charges to a storage node of the pixel.

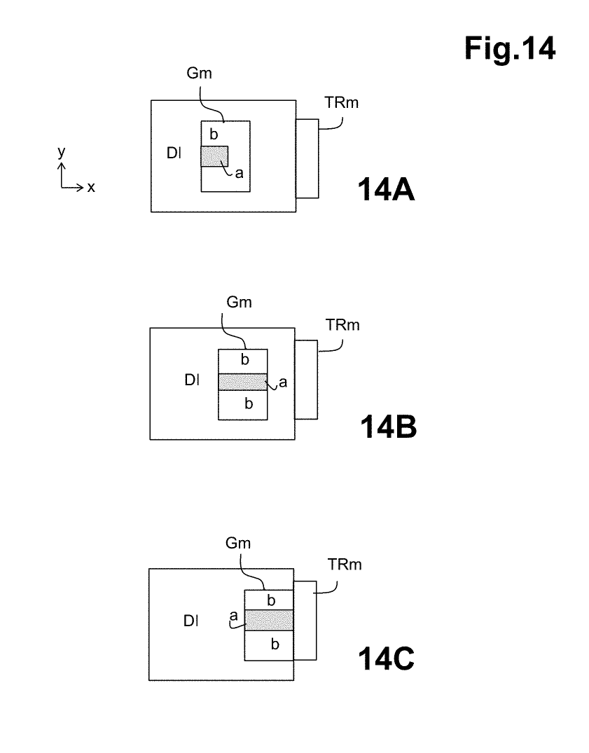

In the case where the region under the multiplication gate is entirely included within the photodiode region, gate configurations in the form of a “U” or strips according to the invention may be envisaged in order to obtain the deeper (a) and shallower (b) well region, as illustrated by the examples 14A and 14B in FIG. 14: the region “a” must be adjacent on at least one edge with the photodiode region (DI=photodiode). The region b may also be adjacent but this is not obligatory.

In the example 14A, the gate part which allows the deeper well region a to be established has one edge adjacent with the photodiode and is surrounded on the other edges by the other gate part which allows the shallower part b to be established.

The example 14B is a configuration with juxtaposed strips, running under the whole gate length; in the example 3 strips: the central strip preferably corresponds to the part which allows the deeper well region a to be established and the two strips on either side establish the shallower well region b.

The example 14C shows the case where the multiplication gate Gm is adjacent to a gate TRm for transfer to the storage node of the pixel. A configuration in the form of strips is used, by which the gate part under which the deeper well region a according to the invention is located is also adjacent to this transfer gate.

These various examples of gate configuration are preferably obtained by differential doping of the gate itself or in the region under the gate. The division of the gate into two sub-gates is less relevant because of the problem of feeding two biasing voltages into the photosensitive region of the pixel.

Other variants and modifications are possible. In particular, as recalled in the introduction, similar devices may be fabricated in which the charges will now be holes rather than electrons. Also, the invention is applicable both to sensors illuminated from the front and to sensors illuminated from the rear (thinned substrate).

1. Active pixel image sensor using CMOS technology formed within a substrate of a first type of conductivity, in which each pixel comprises a photosensitive element producing charges under the effect of light and a structure for multiplication of charges, and in which the multiplication structure comprises at least one isolated multiplication gate adjacent to a pinned diode at a fixed internal potential, the isolated gate being adapted for receiving a series of alternations of potentials, alternately creating under the isolated gate a charge collection well and a barrier, relative to the internal potential level of the diode, wherein the isolated gate and the semiconductor region under the isolated gate are configured in such a manner that the charge collection well created under the gate comprises two parts, a first part, adjacent to the pinned diode, at a potential level further from the internal potential level of the diode than that of a second part, this second part being adjacent or not to the pinned diode.

2. The image sensor of claim 1, wherein the isolated multiplication gate is adjacent to an isolated gate for transferring charges to a storage node of the pixel, so as to be read, and wherein said first part is adjacent on one edge to the pinned diode and adjacent on an opposite edge to the region under the gate for transfer to the storage node.

3. The image sensor of claim 1, wherein the semiconductor region under the isolated multiplication gate comprises two parts, a first part, which is doped with the second type conductivity in order to establish the first part of the well, and a second part which is doped with the first type of conductivity in order to establish the second part of the well.

4. The image sensor of claim 1, wherein the isolated multiplication gate is formed from polycrystalline silicon doped with the second type of conductivity in a first part of gate in order to establish the first part of the well, and doped with the first type of conductivity in a second part of gate, in order to establish the second part of the well.

5. The image sensor of claim 2, wherein the isolated multiplication gate is divided into two sub-gates, a first sub-gate in order to establish the first part of the well and a second sub-gate in order to establish the second part of the well, and in that, during the alternations intended to create a charge collection well under the gate during a multiplication phase, the two sub-gates are configured for simultaneously receiving different high potentials, so as to fix the semiconductor region under the first sub-gate at a potential level which is further from the diode internal potential level than the potential level of the semiconductor region under the second sub-gate.

6. The image sensor of claim 1, wherein the isolated multiplication gate is adjacent to an isolated gate for transferring charges to a storage node of the pixel, so as to be read, and wherein the isolated multiplication gate is divided into two sub-gates, a first sub-gate adjacent on one edge to the pinned diode, in order to establish the first part of the well, and a second sub-gate which surrounds the first sub-gate except on the edge adjacent to the pinned diode, in order to establish the second part of the well, and in that, during the alternations intended, in a multiplication phase, to create a charge collection well under the gate, the two sub-gates are configured for simultaneously receiving different high potentials, in order to fix the semiconductor region under the first sub-gate at a potential level which is further from the diode internal potential level than the potential level of the semiconductor region under the second sub-gate and, in a phase for transfer to the storage node, the two sub-gates are configured for simultaneously receiving identical or different fixed potentials depending on a potential established in the region under the transfer gate.

7. The image sensor of claim 1, comprising a multiplication structure in which the pinned diode is formed by the photosensitive element of the pixel.

8. The image sensor of claim 1, wherein the multiplication structure comprises two isolated multiplication gates on either side of the pinned diode, with a first isolated multiplication gate separated from the photosensitive element of the pixel by an isolated transfer gate, and a second isolated multiplication gate which is adjacent to the isolated gate for transferring charges to the storage node of the pixel, and wherein the second gate is configured such that the first part of the under-gate region is adjacent on one edge to the pinned diode, and is adjacent on an opposite edge to the transfer gate which separates the second gate from the storage node, and the first gate is configured such that the first part of the under-gate region is adjacent on one edge to the pinned diode, and is adjacent or not, on an opposite edge, to the transfer gate which separates the first gate from the photosensitive element.

9. The image sensor of claim 6, wherein the multiplication structure comprises two isolated multiplication gates on either side of the pinned diode, with a first isolated multiplication gate separated from the photosensitive element of the pixel by an isolated transfer gate, and a second isolated multiplication gate which is adjacent to the isolated gate for transferring charges to the storage node of the pixel, and wherein the first and the second gate are configured in an identical manner, such that the first part of the under-gate region is adjacent on one edge to the pinned diode, and the second part surrounds the first part, except on the edge adjacent to the pinned diode.

10. The image sensor of claim 2, comprising a multiplication structure in which the pinned diode is formed by the photosensitive element of the pixel.

11. The image sensor of claim 3, comprising a multiplication structure in which the pinned diode is formed by the photosensitive element of the pixel.

12. The image sensor of claim 4, comprising a multiplication structure in which the pinned diode is formed by the photosensitive element of the pixel.

13. The image sensor of claim 5, comprising a multiplication structure in which the pinned diode is formed by the photosensitive element of the pixel.

14. The image sensor of claim 6, comprising a multiplication structure in which the pinned diode is formed by the photosensitive element of the pixel.

15. The image sensor of claim 2, wherein the multiplication structure comprises two isolated multiplication gates on either side of the pinned diode, with a first isolated multiplication gate separated from the photosensitive element of the pixel by an isolated transfer gate, and a second isolated multiplication gate which is adjacent to the isolated gate for transferring charges to the storage node of the pixel, and wherein the second gate is configured such that the first part of the under-gate region is adjacent on one edge to the pinned diode, and is adjacent on an opposite edge to the transfer gate which separates the second gate from the storage node, and the first gate is configured such that the first part of the under-gate region is adjacent on one edge to the pinned diode, and is adjacent or not, on an opposite edge, to the transfer gate which separates the first gate from the photosensitive element.

16. The image sensor of claim 3, wherein the multiplication structure comprises two isolated multiplication gates on either side of the pinned diode, with a first isolated multiplication gate separated from the photosensitive element of the pixel by an isolated transfer gate, and a second isolated multiplication gate which is adjacent to the isolated gate for transferring charges to the storage node of the pixel, and wherein the second gate is configured such that the first part of the under-gate region is adjacent on one edge to the pinned diode, and is adjacent on an opposite edge to the transfer gate which separates the second gate from the storage node, and the first gate is configured such that the first part of the under-gate region is adjacent on one edge to the pinned diode, and is adjacent or not, on an opposite edge, to the transfer gate which separates the first gate from the photosensitive element.

17. The image sensor of claim 4, wherein the multiplication structure comprises two isolated multiplication gates on either side of the pinned diode, with a first isolated multiplication gate separated from the photosensitive element of the pixel by an isolated transfer gate, and a second isolated multiplication gate which is adjacent to the isolated gate for transferring charges to the storage node of the pixel, and wherein the second gate is configured such that the first part of the under-gate region is adjacent on one edge to the pinned diode, and is adjacent on an opposite edge to the transfer gate which separates the second gate from the storage node, and the first gate is configured such that the first part of the under-gate region is adjacent on one edge to the pinned diode, and is adjacent or not, on an opposite edge, to the transfer gate which separates the first gate from the photosensitive element.

18. The image sensor of claim 5, wherein the multiplication structure comprises two isolated multiplication gates on either side of the pinned diode, with a first isolated multiplication gate separated from the photosensitive element of the pixel by an isolated transfer gate, and a second isolated multiplication gate which is adjacent to the isolated gate for transferring charges to the storage node of the pixel, and wherein the second gate is configured such that the first part of the under-gate region is adjacent on one edge to the pinned diode, and is adjacent on an opposite edge to the transfer gate which separates the second gate from the storage node, and the first gate is configured such that the first part of the under-gate region is adjacent on one edge to the pinned diode, and is adjacent or not, on an opposite edge, to the transfer gate which separates the first gate from the photosensitive element.
